(19) United States
(12) Patent Application Publication
(10) Pub. No.: US 2026/0198289 A1
(43) Pub. Date: Jul. 9, 2026

(54) HIGH POWER DELIVERY SYSTEM FOR AN INTEGRATED CIRCUIT

(71) Applicant: TACHYUM LTD., Las Vegas, NV (US)

(72) Inventors: Radoslav DANILAK, Henderson, NV (US); Pinchas HERMAN, Sunnyvale, CA (US); Stephen DILBECK, San Ramon, CA (US)

(73) Assignee: TACHYUM LTD., Las Vegas, NV (US)

(21) Appl. No.: 19/013,606

(22) Filed: Jan. 8, 2025

(51) Int. Cl. H01L 23/528; H01L 23/498

(52) U.S. Cl. CPC H10W 20/427; H10W 70/635; H10W 90/701

(57) ABSTRACT

A die assembly is provided. The assembly may include a die having electrical contacts on a bottom side and a top side. A first electrical contact on the bottom side of the die is configured to receive a first voltage from a voltage source for powering at least a portion of the die and to communicate the first voltage to a second electrical contact on the top side of the die. A first voltage regulator mounted above the top side of the die includes on a bottom side thereof: an input electrical contact to receive the first voltage from the second electrical contact of the die; an output electrical contact to output a second voltage, lower than the first voltage, to a third electrical contact of the die.

### FIELD OF THE INVENTION

Various embodiments described herein relate generally to providing power to an integrated circuit from voltage regulators that are mounted above the integrated circuit.

### BACKGROUND

The developments described in this section are known to the inventors. However, unless otherwise indicated, it should not be assumed that any of the developments described in this section qualify as prior art merely by virtue of their inclusion in this section, or that these developments are known to a person of ordinary skill in the art.

A die, such as by way of non-limiting example a semiconductor die (e.g., GPU, CPU, DPU, TPU, AI chips), is the physical piece of silicon within a semiconductor chip that contains the integrated circuit (IC) for a processor. As processors become more complex and drive more calculations per second, they experience a corresponding increased demand for power. The physical mechanisms to supply that increasing amount of power have become a challenge relative to available space in the supporting environment.

Referring now to FIG. 1, a die 102 is provided on a circuit board 104, and needs a certain wattage, such as 900 watts distributed 900 amp at 1 volt. A main voltage source/power supply is provided by a power supply 120. Several voltage regulators 106 are placed on the circuit board 104 and convert the high voltage source into six (6) individual feeds of 1 volt at about 150 amps. The 1 volt feeds pass through package balls 108, a substrate 110, such for example a package substrate, and flip chip bumps 112 to reach die 102.

As shown in FIG. 1, the voltage regulators 106 are shown to the left and right of the die 102, and take up actual space on the circuit board. Six (6) such voltage regulators 106 at 150 watts each (1 volt×150 amps) located on the lateral sides of die 102 can thus provide the 900 watts needed for the die 102.

There is only so much space on the circuit board to accommodate voltage regulators 106, and thus only so much power that the voltage regulators 106 can collectively supply. There is also significant power loss from the distance that the power has to travel from the voltage regulators 106 to reach the die 102.

Referring now to FIG. 2, a more recent arrangement of components is shown. In this arrangement the components are stacked in order from bottom-to-top as voltage regulators 202, printed circuit board 204 with through pathways 206, package balls 208, a substrate 210 with its own internal pathways, flip chip bumps 212, and the die 214 at the top.

A main power supply 216, such as a 12 volt power source, feeds the voltage regulators 202. The voltage regulators 202 output power signals that travel through the pathways 206 in the printed circuit board 204, through the package balls 208, through the substrate 210, through the flip chip bumps 212, and to the die 214.

Since the voltage regulators 202 only output about 1 volt and the die 214 needs about 900 watts, some 900 amps must convey through the package balls. Each package ball 208 can only carry on the order of 1 amps. Transmission of 900 amps thus requires on the order of 1800 package balls—900 for the power signals, and another 900 for the ground return. Each die 214 can accommodate about 7000 package balls 208, so the power requirements alone use almost 25% of the available package balls, leaving only about 75% of the package balls 208 for data transmission.

The above structure resists scaling to support dies with higher power needs. If a new die increases its power consumption to 2000 watts, then it would need 4000 of the 7000 package balls 208—over half, leaving less than half for data transmission. If yet another new die increases its power consumption to 3000 watts, then it would need 6000 of the 7000 package balls—almost all and leaving insufficient package for data transmission. A 4000 watt die would be impossible to handle, as there would not be enough package balls 208 for the power alone.

### SUMMARY

In one general aspect, a processor assembly may include a die having electrical contacts on a bottom side and a top side, and at least one electrical power pathway extending from a first electrical contact on the bottom side to a second electrical contact on the top side, and having a third electrical contact on the top side for receiving power to operate the die. The processor assembly may also include the first electrical contact on the bottom side of the die being configured to receive a first voltage from a voltage source for powering at least a portion of the die and to communicate the first voltage to the second electrical contact on the top side of the die. The processor assembly may furthermore include a first voltage regulator mounted above the top side of the die, the first voltage regulator including on a bottom side thereof: an input electrical contact to receive the first voltage from the second electrical contact of the die; an output electrical contact to output a second voltage, lower than the first voltage, to the third electrical contact of the die; and where power received at the first electrical contact travels through the die, is received and reduced by the first voltage regulator, and the reduced power is returned to the third electrical contact of the die to power the die.

The above aspect may include one or more of the following optional features. The at least one electrical power pathway may be defined at least in part by at least one Through Silicon Vias (TSV) that passes power through the die. The first voltage regulator may be configured to withstand the heat generated by the die, be a silicon voltage regulator and/or be less than about 0.1 mm thick. Micro bumps may be between and connecting the first voltage regulator to the die. The die may be mounted on a substrate by flip chip bumps, and the substrate may be mounted on a printed circuit board by package balls. The voltage source may provide power for the die through a collective pathway defined by at least the printed circuit board, at least some of the package balls, the substrate, at least some of the flip chip bumps, the first electrical contact on the die, the second electrical contact on the die, a first at least some of the micro bumps, the first voltage regulator, a second at least some of the micro bumps, and the third electrical contact of the die. A second voltage regulator may be mounted on or below the printed circuit board and may be at least a portion of the voltage source.

In another general aspect, a processor assembly may include a die having electrical power pathways extending from a first set of electrical contacts on a bottom side of the die to a second set of electrical contact on a top side of the die, and having a third set of electrical contacts on the top side for receiving power to operate the die. The processor assembly may also include the first set of electrical contacts on the bottom side of the die being configured to receive a first voltage from a voltage source for powering at least a portion of the die and to communicate the first voltage to the second set of electrical contacts on the top side of the die. The processor assembly may furthermore include a plurality of first voltage regulators mounted above the top side of the die, the plurality of first voltage regulators including on a bottom side thereof: a set of input electrical contacts to receive the first voltage from at least some of the second set of electrical contact of the die; a set of output electrical contacts to output a second voltage, lower than the first voltage, to at least some of the third set of electrical contact of the die; and where power received at the first set of electrical contact travels through the die, is received and reduced by the plurality of first voltage regulators, and the reduced power is returned to the third set of electrical contacts of the die to at least partially power the die.

The above aspect may have one or more optional features. The electrical power pathways may be defined at least in part by at least one Through Silicon Vias (TSV) that passes power through the die. The plurality of first voltage regulators may be configured to withstand the heat generated by the die, be silicon voltage regulators, and/or less than about 0.1 mm thick. Micro bumps may be between and connecting the plurality of first voltage regulators to the die. The die may be mounted on a substrate by flip chip bumps and the substrate may be mounted on a printed circuit board by package balls. The voltage source may provide power for the die through a collective pathway defined by at least the printed circuit board, at least some of the package balls, the substrate, at least some of the flip chip bumps, the first set of electrical contacts on the die, the second set of electrical contacts on the die, a first at least some of the micro bumps, the first voltage regulators, a second at least some of the micro bumps, and the third set of electrical contacts of the die. A plurality of second voltage regulators may be mounted on or below the printed circuit board or on or below the substrate and be at least a portion of the voltage source.

### DRAWINGS

Various embodiments in accordance with the present disclosure will be described with reference to the drawings, in which:

FIG. 1 shows a prior art arrangements of components to provide power to a die.

FIG. 2 shows another prior art arrangements of components to provide power to a die.

FIG. 3 shows an arrangement of components to provide power to a die according to an embodiment of the invention.

FIG. 4 shows an arrangement of components to provide power to a die according to another embodiment of the invention.

FIG. 5 shows an arrangement of components to provide power to a die according to yet another embodiment of the invention.

### DETAILED DESCRIPTION

In the following description, various embodiments will be illustrated by way of example and not by way of limitation in the figures of the accompanying drawings. References to various embodiments in this disclosure are not necessarily to the same embodiment, and such references mean at least one. While specific implementations and other details are discussed, it is to be understood that this is done for illustrative purposes only. A person skilled in the relevant art will recognize that other components and configurations may be used without departing from the scope and spirit of the claimed subject matter.

References to one or an embodiment in the present disclosure can be, but not necessarily are, references to the same embodiment; and, such references mean at least one of the embodiments.

Reference to any “example” herein (e.g., “for example”, “an example of”, by way of example” or the like) are to be considered non-limiting examples regardless of whether expressly stated or not.

Reference to “one embodiment” or “an embodiment” means that a particular feature, structure, or characteristic described in connection with the embodiment is included in at least one embodiment of the disclosure. The appearances of the phrase “in one embodiment” in various places in the specification are not necessarily all referring to the same embodiment, nor are separate or alternative embodiments mutually exclusive of other embodiments. Moreover, various features are described which may be exhibited by some embodiments and not by others. Similarly, various features are described which may be features for some embodiments but not other embodiments.

The terms used in this specification generally have their ordinary meanings in the art, within the context of the disclosure, and in the specific context where each term is used. Alternative language and synonyms may be used for any one or more of the terms discussed herein, and no special significance should be placed upon whether or not a term is elaborated or discussed herein. Synonyms for certain terms are provided. A recital of one or more synonyms does not exclude the use of other synonyms. The use of examples anywhere in this specification including examples of any terms discussed herein is illustrative only, and is not intended to further limit the scope and meaning of the disclosure or of any exemplified term. Likewise, the disclosure is not limited to various embodiments given in this specification.

Without intent to limit the scope of the disclosure, examples of instruments, apparatus, methods and their related results according to the embodiments of the present disclosure are given below. Note that titles or subtitles may be used in the examples for convenience of a reader, which in no way should limit the scope of the disclosure. Unless otherwise defined, technical and scientific terms used herein have the meaning as commonly understood by one of ordinary skill in the art to which this disclosure pertains. In the case of conflict, the present document, including definitions will control.

Several definitions that apply throughout this disclosure will now be presented. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder.

The term “comprising” when utilized means “including, but not necessarily limited to”; it specifically indicates open-ended inclusion or membership in the so-described combination, group, series and the like.

The term “a” means “one or more” unless the context clearly indicates a single element.

The term “about” when used in connection with a numerical value means a variation consistent with the range of error in equipment used to measure the values, for which ±20% may be expected. Non-numerical uses of “about” carry similar variation.

The term “substantial”, “substantially” or the like is used as a modifier to imply “approximate” rather than “perfect.” It is a term of approximation, not a term of degree.

“First,” “second,” etc., re labels to distinguish components or blocks of otherwise similar names, but does not imply any sequence or numerical limitation.

“And/or” for two possibilities means either or both of the stated possibilities (“A and/or B” covers A alone, B alone, or both A and B take together), and when present with three or more stated possibilities means any individual possibility alone, all possibilities taken together, or some combination of possibilities that is less than all of the possibilities. The language in the format “at least one of A . . . and N” where A through N are possibilities means “and/or” for the stated possibilities (e.g., at least one A, at least one N, at least one A and at least one N, etc.).

When an element is referred to as being “connected,” or “coupled,” to another element, it can be directly connected or coupled to the other element or intervening elements may be present. By contrast, when an element is referred to as being “directly connected,” or “directly coupled,” to another element, there are no intervening elements present. Other words used to describe the relationship between elements should be interpreted in a like fashion (e.g., “between,” versus “directly between,” “adjacent,” versus “directly adjacent,” etc.).

As used herein, the term “front”, “rear”, “left,” “right,” “top” and “bottom” or other terms of direction, orientation, and/or relative position are used for explanation and convenience to refer to certain features of this disclosure. However, these terms are not absolute, and should not be construed as limiting this disclosure.

Shapes as described herein are not considered absolute. As is known in the art, surfaces often have waves, protrusions, holes, recesses, etc. to provide rigidity, strength and functionality. All recitations of shape (e.g., cylindrical) herein are to be considered modified by “substantially” regardless of whether expressly stated in the disclosure or claims, and specifically accounts for variations in the art as noted above.

It should also be noted that in some alternative implementations, the functions/acts noted may occur out of the order noted in the figures. For example, two steps disclosed or shown in succession may in fact be executed substantially concurrently or may sometimes be executed in the reverse order, depending upon the functionality/acts involved.

Specific details are provided in the following description to provide a thorough understanding of embodiments. However, it will be understood by one of ordinary skill in the art that embodiments may be practiced without these specific details. For example, systems may be shown in block diagrams so as not to obscure the embodiments in unnecessary detail. In other instances, well-known processes, structures and techniques may be shown without unnecessary detail in order to avoid obscuring example embodiments.

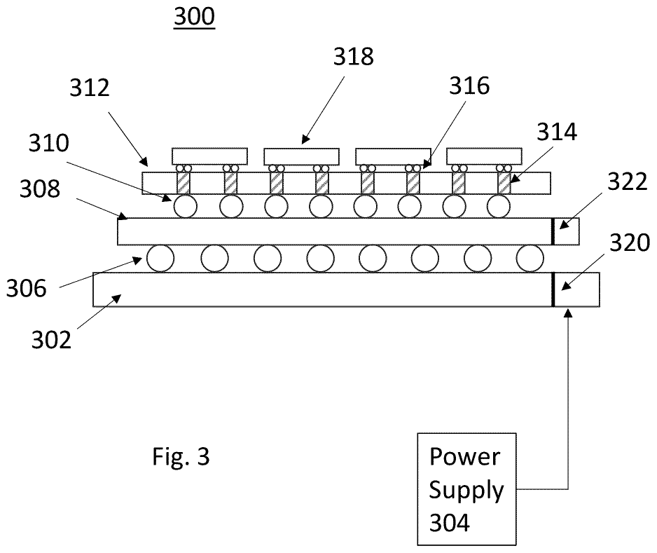

Referring now to FIG. 3, a die assembly 300 according to an embodiment of the invention is shown. In this arrangement the components are stacked in order from bottom-to-top as a printed circuit board 302 with surface and/or internal pathways, package balls 306, a substrate 308 with surface and/or internal pathways, flip chip bumps 310, die 312 with top-bottom Through Silicon Vias (TSV) 314, micro bumps 316, and voltage regulators 318. Die 312 has electrical contacts on the top side and bottom side (including but not limited to TSVs 314) to facilitate power and/or data transmission into and out of die 312. Substrate 308 may be a single layer, or multiple layers, such as a package substrate and/or a complex package buildup including a interposer (e.g., silicon, glass).

A main voltage source 304, such as a 12 v power source, provides voltage that travels through the pathways in the printed circuit board 302 (pathways represented generally by 320), through the package balls 306, through pathways in the substrate 308 (pathways represented generally by 322), through the flip chip bumps 310, through the TSVs 314 in the die 312 to the micro bumps 316 to the voltage regulators 318. The voltage regulators will generate the individual 1 volt voltage signals and send them to the die 312 through the micro bumps 316.

The above configuration provides a number of electrical power pathways through the die 312 for power to pass through the die to reach the voltage regulators 318, and then receive the reduced power provided by the voltage regulators 318. Individually, a first electrical contact on the bottom side of the die 312 receives electrical power, and a second electrical contact on the top side of the die 312 that is in electrical communication with the first electrical contact transmits the power to the one of the voltage regulators 318. A third electrical contact on the top side of the die 312 receives reduced power from one of the voltage regulators 318 to partially operate the die 312.

Similarly, a voltage regulator 318 mounted above the top side of the die 312 has on a bottom side thereof an input electrical contact to receive the voltage from the second electrical contact of the die, and an output electrical contact to output a second voltage, lower than the first voltage, to the third electrical contact of the die.

It is to be understood that there may be hundreds, if not thousands, of such electrical contacts on the die 312 and the voltage regulators 318.

The above embodiment requires far fewer package balls 306 than the prior art. In this embodiment, the full power from power supply 304 can be sent through a smaller number of package balls 306. By way of non-limiting example, for the same 12 v power source to power 1000 watts of die, only about 83 amps (1000 w/12 v) must convey through the package balls 306. Each package ball can only carry about 1 amp. Transmission of 83 amps thus requires about 166 package balls—about 83 for the power signals, and about another 83 for the ground return. Each die 312 can accommodate about 7000 package balls, so the power requirements use less than about 3% of the package balls compared to almost 30% of the prior art.

This embodiment also allows scaling that the prior art cannot accommodate. As discussed above, in the prior art a 2000 watt die would use over 50% of the package balls, a 3000 watt die would use too may package balls to be practical, and a 4000 watt die could not be accommodated. In the embodiment above, a 2000 watt die would use 5% of the package balls 306, and a 4000 watt die could be accommodated with only about 10% of the package balls 306. The overwhelming bulk of the package balls 306 remain available for data transmission.

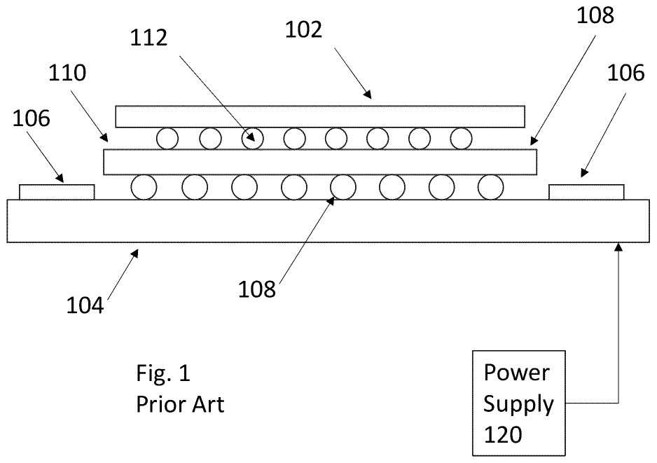

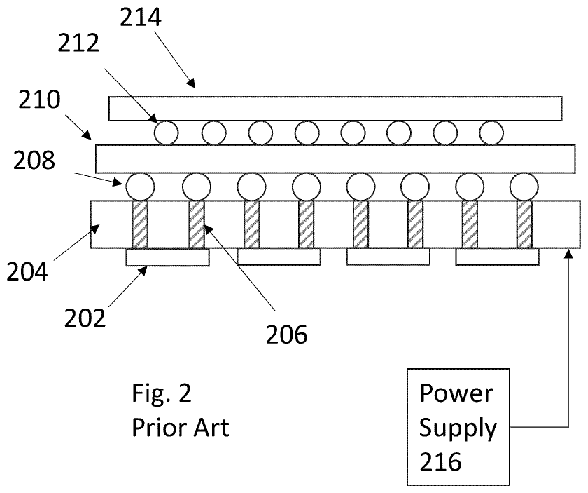

In the above embodiment, the voltage regulators can also be made smaller and run off lower power from power supply 304. For example, the power supply need only provide 3-5 volts. Even at 3.3 volts, a 1000 watt die would only need about 300 amps and about 600 package balls 306 (300 for power, 300 for ground). A 3000 watt die would only need about 900 amps and 1800 package balls 306 (900 for power, 900 for ground)—the same amount of package balls 306 needed for a 900 watt processor using the prior art of FIG. 1 or 2.

The number of voltage regulators is based on the wattage needs of the die 312 relative to the output wattage of the voltage regulators 318. By way of non-limiting example, for a 1000 watt die 312 where each voltage regulator 318 can provide two (2) watts, then at least about 500 voltage regulators 318 would be used. If each voltage regulator 318 could provide four (4) watts, then at least about 250 voltage regulators 318 would be used for a 1000 watt die 312.

Since the voltage regulators 318 are above the die 312, heat generated by the die 312 can be a consideration in the selection of the type of voltage regulator 318. Voltage regulators should be selected to withstand the temperature generated by die during standard use and for extended periods (e.g., years).

Thin voltage regulators on the order of 0.05-0.2 mm or less may be appropriate for this purpose. Voltage regulators that dissipate heat quickly and are consistent with the sizing, such as silicon voltage regulators, may be appropriate. More traditional inductive or capacitive voltage regulators may be too large and/or heat sensitive for extended use in this environment.

Package balls 306, flip chip bumps 310, and micro bumps 316 are solder balls that vary in size, with flip-chip bumps being smaller than package balls and larger than micro bumps. By way of non-limiting example, package balls 306 may be about 0.65 mm to 0.8 mm diameter, flip chip bumps 310 may be about 40 μm to 100 μm, and micro bumps 316 may be about 25 μm to 50 μm.

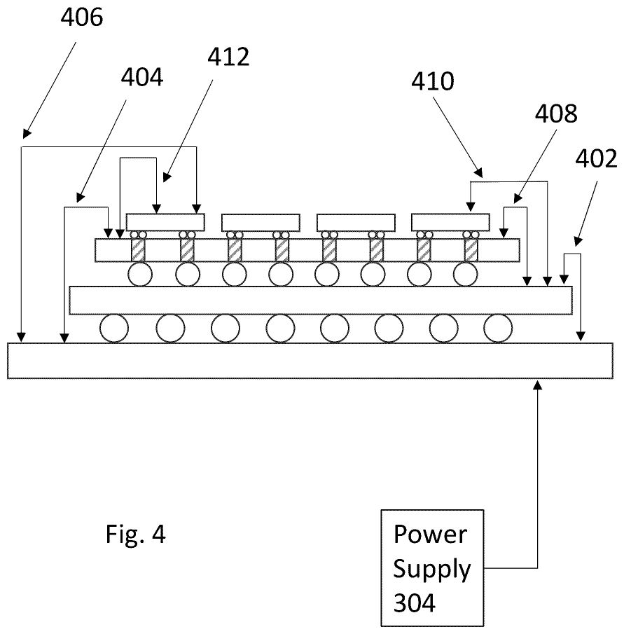

In the design of FIG. 3, power from power supply 304 reached the voltage regulators 318 through the intervening package balls 306, flip chip bumps 310, and micro bumps 316. However, the invention is not so limited, and some of the power could at least partially pass through alternative pathways. Referring now to FIG. 4, various other pathways could be used.

By way of non-limiting example, power could be supplied by a pathway 402 from the printed circuit board 302 to the substrate 308, where such pathway 402 does not utilize the package balls 306. Power could be at least partially supplied by a pathway 404 from the printed circuit board 302 to the die 312, where such pathway 402 does not utilize the package balls 306 or the flip chip bumps 310. Power could be at least partially supplied by a pathway 406 from the printed circuit board 302 to the voltage regulators 318, where such pathway 404 does not utilize the package balls 306, the flip chip bumps 310, or the micro bumps 316. Power could be at least partially supplied by a pathway 406 from the printed circuit board 302 to the voltage regulators 318, where such pathway 406 does not utilize the package balls 306, the flip chip bumps 310, or the micro bumps 316.

Power could be at least partially supplied by a pathway 408 from the substrate 308 to the die 312, where such pathway 408 does not utilize the flip chip bumps 310. Power could be at least partially supplied by a pathway 410 from the substrate 308 to the voltage regulators 318, where such pathway 410 does not utilize the flip chip bumps 310 or the micro bumps 316. Power could be at least partially supplied by a pathway 412 from the die 312 to the voltage regulators 318, where such pathway 410 does not utilize the micro bumps 316.

The methodology to create such pathways is known to those of skill in the art and not further discussed herein.

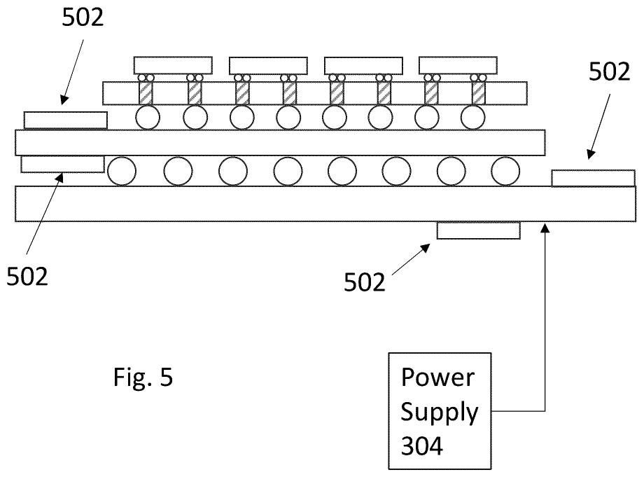

In the design of FIG. 3, the voltage regulators are above the die 312 as voltage regulators 318. However, the invention is not so limited. Referring now to FIG. 5, additional voltage regulators 502 could be deployed on the printed circuit board 302, underneath printed circuit board 302, on the substrate 306, and/or beneath the substrate 306. These additional voltage regulators 502 could provide some or all of the power for voltage regulators 318. By way of non-limiting example, if power supply 304 is a 12 volt power supply, voltage regulators 502 could reduce that voltage to 3.3 volts, which is then sent to voltage regulators 318 for further reduction to 1 volt signals for die 312.

The specification and drawings are to be regarded in an illustrative rather than a restrictive sense. It will, however, be evident that various modifications and changes may be made thereunto without departing from the broader spirit and scope of the invention as set forth in the claims.

What is claimed is:

1. A die assembly, comprising:
a die having electrical contacts on a bottom side and a top side, and at least one electrical power pathway extending from a first electrical contact on the bottom side to a second electrical contact on the top side, and having a third electrical contact on the top side for receiving power to operate the die;
the first electrical contact on the bottom side of the die being configured to receive a first voltage from a voltage source for powering at least a portion of the die and to communicate the first voltage to the second electrical contact on the top side of the die;
a first voltage regulator mounted above the top side of the die, the first voltage regulator including on a bottom side thereof:
an input electrical contact to receive the first voltage from the second electrical contact of the die;
an output electrical contact to output a second voltage, lower than the first voltage, to the third electrical contact of the die; and
wherein power received at the first electrical contact travels through the die, is received and reduced by the first voltage regulator, and the reduced power is returned to the third electrical contact of the die to power the die.

2. The die assembly of claim 1, where the at least one electrical power pathway is defined at least in part by at least one Through Silicon Vias (TSV) that passes power through the die.

3. The die assembly of claim 1, wherein the first voltage regulator is configured to withstand the heat generated by the die.

4. The die assembly of claim 3, wherein the first voltage regulator is a silicon voltage regulator.

5. The die assembly of claim 3, wherein the first voltage regulator is less than about 0.1 mm thick.

6. The die assembly of claim 1, further comprising:
micro bumps between and connecting the first voltage regulator to the die.

7. The die assembly of claim 6, further comprising:
the die being mounted on a substrate by flip chip bumps.

8. The die assembly of claim 7, further comprising:
the substrate being mounted on a printed circuit board by package balls.

9. The die assembly of claim 8, wherein the voltage source provides power for the die through a collective pathway defined by at least the printed circuit board, at least some of the package balls, the substrate, at least some of the flip chip bumps, the first electrical contact on the die, the second electrical contact on the die, a first at least some of the micro bumps, the first voltage regulator, a second at least some of the micro bumps, and the third electrical contact of the die.

10. The die assembly of claim 8, further comprising a second voltage regulator mounted on or below the printed circuit board and comprising at least a portion of the voltage source.

11. A die assembly, comprising:
a die having electrical power pathways extending from a first set of electrical contacts on a bottom side of the die to a second set of electrical contact on a top side of the die, and having a third set of electrical contacts on the top side for receiving power to operate the die;
the first set of electrical contacts on the bottom side of the die being configured to receive a first voltage from a voltage source for powering at least a portion of the die and to communicate the first voltage to the second set of electrical contacts on the top side of the die;
a plurality of first voltage regulators mounted above the top side of the die, the plurality of first voltage regulators including on a bottom side thereof:
a set of input electrical contacts to receive the first voltage from at least some of the second set of electrical contact of the die;
a set of output electrical contacts to output a second voltage, lower than the first voltage, to at least some of the third set of electrical contact of the die; and
wherein power received at the first set of electrical contact travels through the die, is received and reduced by the plurality of first voltage regulators, and the reduced power is returned to the third set of electrical contacts of the die to at least partially power the die.

12. The die assembly of claim 11, where the electrical power pathways is defined at least in part by at least one Through Silicon Vias (TSV) that passes power through the die.

13. The die assembly of claim 11, wherein the plurality of first voltage regulators are configured to withstand the heat generated by the die.

14. The die assembly of claim 13, wherein the plurality of first voltage regulators are silicon voltage regulators.

15. The die assembly of claim 13, wherein the plurality of first voltage regulators are less than about 0.1 mm thick.

16. The die assembly of claim 11, further comprising:
micro bumps between and connecting the plurality of first voltage regulators to the die.

17. The die assembly of claim 16, further comprising:
the die being mounted on a substrate by flip chip bumps.

18. The die assembly of claim 17, further comprising:
the substrate being mounted on a printed circuit board by package balls.

19. The die assembly of claim 18, wherein the voltage source provides power for the die through a collective pathway defined by at least the printed circuit board, at least some of the package balls, the substrate, at least some of the flip chip bumps, the first set of electrical contacts on the die, the second set of electrical contacts on the die, a first at least some of the micro bumps, the first voltage regulators, a second at least some of the micro bumps, and the third set of electrical contacts of the die.

20. The die assembly of claim 18, further comprising a plurality of first voltage regulators mounted on or below the printed circuit board or on or below the substrate and comprising at least a portion of the voltage source.
